(19) United States
(12) Patent Application Publication
(10) Pub. No.: US 2022/0163484 A1
(43) Pub. Date: May 26, 2022

(54) EDDY CURRENT SENSOR

(71) Applicant: EBARA CORPORATION, Tokyo (JP)

(72) Inventors: Hiroto Yamada, Tokyo (JP); Taro Takahashi, Tokyo (JP); Hiroaki Shibue, Tokyo (JP)

(21) Appl. No.: 17/533,386

(22) Filed: Nov. 23, 2021

(30) Foreign Application Priority Data
Nov. 25, 2020 (JP) 2020-195199

(51) Int. Cl. G01N 27/90; G01N 27/904

(52) U.S. Cl. CPC G01N 27/9006; G01N 27/904

(57) ABSTRACT

An eddy current sensor for detecting an eddy current that can be generated in a wafer includes a magnetic core. The core has a base, a central wall provided on the base in the center of the base in a first direction, and end walls provided on the base at either end portion of the base in the first direction. The eddy current sensor includes exciting coils which are disposed on the end walls and which generates an eddy current in the wafer, and a detecting coil which is disposed on the central wall and which detects the eddy current.

### FIELD OF THE INVENTION

The present invention relates to an eddy current sensor.

### BACKGROUND ART

Eddy current sensors are used to measure film thickness, displacement, and the like. In the following, an eddy current sensor will be described by taking film thickness measurement as an example. An eddy current sensor used to measure film thickness is used in a step (polishing step) for fabricating a semiconductor device, for example. In the polishing step, the eddy current sensor is used as follows. As semiconductor devices become more highly integrated, the circuit interconnects are becoming finer, and the distance between interconnects is becoming narrower. Accordingly, it is necessary to planarize the surface of an object to be polished (a substrate such as a semiconductor wafer) containing a conductor, and polishing is performed by a polishing apparatus as one means of planarization.

The polishing apparatus is provided with a polishing table for holding a polishing pad for polishing the object to be polished, and a top ring (holding unit) for holding and pressing the object to be polished against the polishing pad. The polishing table and the top ring are each rotationally driven by a driving unit (a motor, for example). An abrasive-containing liquid (slurry) is made to flow onto the polishing pad, and by pressing the object to be polished that is held by the top ring against the polishing pad, the object to be polished is polished.

In the polishing apparatus, if the object to be polished is not polished adequately, insulation between circuits may not be achieved and there is a risk of shorting. On the other hand, over-polishing may lead to problems such as an increase in resistance due to the reduction in the cross-sectional area of the interconnects, or alternatively, the interconnects themselves may be completely eliminated and the circuit itself may not be formed. Consequently, it is demanded that the polishing apparatus detect the optimal polishing endpoint.

The disclosure of Japanese Patent Laid-Open No. 2011-23579 is related to such technology. In the cited technology, an eddy current sensor using three coils is used to detect the polishing endpoint. As illustrated in FIG. 5 of Japanese Patent Laid-Open No. 2011-23579, from among the three coils, a detecting coil and a dummy coil form a series circuit, both ends of which are connected to a resistance bridge circuit having a variable resistance. By adjusting the balance with the resistance bridge circuit, it is possible to adjust the zero point such that the output of the resistance bridge circuit goes to zero when the film thickness is zero. The output of the resistance bridge circuit is input into a synchronous detector circuit, as illustrated in FIG. 6 of Japanese Patent Laid-Open No. 2011-23579. The synchronous detector circuit extracts a resistance component (R), a reactance component (X), an amplitude component (Z), and a phase output (tan⁻¹R/X) associated with changes in film thickness from the input signal.

With regard to the detection method using a bridge circuit according to the related art, the magnitude of the resistance adjustment when adjusting the zero point is extremely small compared to the magnitude of the overall resistance forming the bridge circuit. As a result, the magnitude of the temperature change for the overall resistance is non-negligible when compared to the magnitude of the resistance adjustment when adjusting the zero point. Because changes in temperature cause changes in properties such as the resistance value and the parasitic capacitance having a resistance, the properties of the bridge circuit are sensitive to the influence exerted by changes in the surrounding environment of the resistance. As a result, a problem is that the zero-point described above shifts easily, and the accuracy of the film thickness measurement is lowered.

### SUMMARY

A first aspect adopts a configuration of an eddy current sensor for detecting an eddy current that can be generated in a conductor, the eddy current sensor comprising: a magnetic core having a base, a central wall provided on the base in a center of the base in a first direction, and end walls provided on the base at either end portion of the base in the first direction; exciting coils, disposed on the end walls, that are configured to generate an eddy current in the conductor; and a detecting coil, disposed on the central wall, that is configured to detect the eddy current.

A second aspect adopts the configuration of the eddy current sensor according to the first aspect, wherein a distance on the end walls from the exciting coils to the base is shorter than a distance on the central wall from the detecting coil to the base.

A third aspect adopts the configuration of the eddy current sensor according to the first or second aspect, wherein a distance on the end walls from the exciting coils to the base is no more than half a distance on the end walls from ends facing the conductor to the base.

A fourth aspect adopts the configuration of the eddy current sensor according to any one of the first to third aspects, and further comprises a dummy coil, disposed on either the central wall or the end walls, that is configured to detect the eddy current.

A fifth aspect adopts the configuration of the eddy current sensor according to any one of first to fourth aspects, wherein a cross-sectional area of the central wall perpendicular to a second direction proceeding from the base toward the conductor is smaller than a cross-sectional area of the end walls perpendicular to the second direction.

A sixth aspect adopts the configuration of a polishing apparatus comprising: a polishing table to which a polishing pad is attached for polishing a substrate containing the conductor; a motor (a table driving unit) configured to rotationally drive the polishing table; a top ring configured to hold the substrate and press the substrate against the polishing pad; the eddy current sensor according to any one of the first to fifth aspects, disposed inside the polishing table and configured to detect the eddy current created in the conductor; and an endpoint detection controller configured to calculate film thickness data about the conductor from the detected eddy current.

A seventh aspect adopts the configuration of the polishing apparatus according to the sixth aspect, wherein the first direction is substantially the same as a direction joining a center of the core to a rotation center of the polishing table.

### BRIEF DESCRIPTION OF DRAWINGS

FIG. 1 is a schematic diagram illustrating an overall configuration of a polishing apparatus according to an embodiment of the present invention;

FIG. 2 is a plan view illustrating relationship among a polishing table, an eddy current sensor, and a semiconductor wafer;

FIGS. 3A and 3B are diagrams illustrating a configuration of an eddy current sensor, in which FIG. 3A is a block diagram illustrating a configuration of the eddy current sensor and FIG. 3B is an equivalent circuit diagram of the eddy current sensor;

FIG. 4A is a schematic diagram illustrating an example of a configuration of an eddy current sensor according to the related art, and FIG. 4B is a schematic diagram illustrating an example of the configuration of the eddy current sensor according to the embodiment of the present invention;

FIG. 5 is a schematic diagram of a bridge circuit;

FIG. 6A is a diagram illustrating flux of an eddy current sensor according to the related art, and FIG. 6B is a diagram illustrating flux of an eddy current sensor according to the embodiment of the present invention;

FIGS. 7A and 7B are diagrams illustrating the flux generated by the eddy current sensor according to the technology of the related art;

FIGS. 8A and 8B are diagrams illustrating the flux generated by the eddy current sensor according to the present embodiment;

FIG. 9 is a schematic diagram for explaining the function of a dummy coil;

FIG. 10 is a schematic diagram illustrating a configuration of an eddy current sensor according to another embodiment of the present invention;

FIGS. 11A and 11B are diagrams illustrating relationship between a movement direction of the eddy current sensor according to the technology of the related art and a first direction; and

FIGS. 12A and 12B are diagrams illustrating relationship between a movement direction of the eddy current sensor according to the present embodiment and the first direction.

### DESCRIPTION OF EMBODIMENTS

Hereinafter, embodiments of the present invention will be described with reference to the drawings. Note that in the following embodiments, the same or corresponding members may be denoted with the same signs, and duplicate description of such members may be omitted. Moreover, the features described in each embodiment are also applicable to another embodiment as long as there is no contradiction.

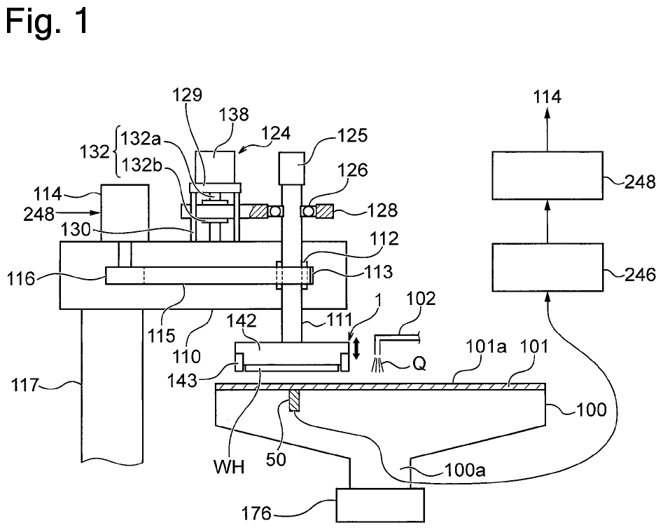

FIG. 1 is a schematic diagram illustrating an overall configuration of a polishing apparatus according to the present invention. As illustrated in FIG. 1, the polishing apparatus is provided with a polishing table 100 configured such that a polishing pad for polishing a substrate containing a conductor is attached, a motor 176 (table driving unit) configured to rotationally drive the polishing table 100, a top ring (holding unit) 1 configured to hold and press the substrate such as a semiconductor wafer treated as the object to be polished against the polishing pad, an eddy current sensor 50 disposed inside the polishing table 100 and configured to detect an eddy current formed in the conductor in association with the rotation of the polishing table 100, and an endpoint detection controller 246 configured to calculate conductor thickness data from the detected eddy current.

The polishing table 100 is coupled to the motor 176, which acts as a driving unit disposed underneath, via a table spindle 100a, and is rotatable about the table spindle 100a. A polishing pad 101 is attached to the top surface of the polishing table 100, and the surface 101a of the polishing pad 101 forms a polishing surface that polishes a semiconductor wafer WH. A polishing liquid supply nozzle 102 is installed above the polishing table 100, and a polishing liquid Q is supplied onto the polishing pad 101 on top of the polishing table 100 by the polishing liquid supply nozzle 102. As illustrated in FIG. 1, the eddy current sensor 50 is embedded inside the polishing table 100.

The top ring 1 basically includes a top ring body 142 that presses the semiconductor wafer WH against the polishing surface 101a, and a retainer ring 143 that holds the outer edge of the semiconductor wafer WH and keeps the semiconductor wafer WH from flying off the top ring.

The top ring 1 is connected to a top ring shaft 111, and the top ring shaft 111 is moved up and down with respect to a top ring head 110 by a raising/lowering mechanism 124. By the up and down movement of the top ring shaft 111, the entire top ring 1 is raised or lowered and positioned with respect to the top ring head 110. Note that a rotary joint 125 is attached to the upper end of the top ring shaft 111.

The raising/lowering mechanism 124 that moves the top ring shaft 111 and the top ring 1 up and down is provided with a bridge 128 that rotatably supports the top ring shaft 111 through a bearing 126, a ball screw 132 attached to the bridge 128, a support stand 129 supported by a support column 130, and an AC servo motor 138 provided on the support stand 129. The support stand 129 that supports the servo motor 138 is secured to the top ring head 110 through the support column 130.

The ball screw 132 is provided with a screw shaft 132a coupled to the servo motor 138 and a nut 132b with which the screw shaft 132a engages. The top ring shaft 111 is configured to move up and down as one with the bridge 128. Consequently, when the servo motor 138 is driven, the bridge 128 moves up and down through the ball screw 132, thereby causing the top ring shaft 111 and the top ring 1 to move up and down.

Additionally, the top ring shaft 111 is coupled to a rotating cylinder 112 through a key (not illustrated). The rotating cylinder 112 is provided with a timing pulley 113 on the outer periphery thereof. A top ring motor 114 is secured to the top ring head 110, and the timing pulley 113 is connected to a timing pulley 116 provided in the top ring motor 114 through a timing belt 115. Consequently, by rotationally driving the top ring motor 114, the rotating cylinder 112 and the top ring shaft 111 rotate as one through the timing pulley 116, the timing belt 115, and the timing pulley 113, and the top ring 1 rotates. Note that the top ring head 110 is supported by a top ring head shaft 117 rotationally supported by a frame (not illustrated).

In the polishing apparatus configured as illustrated in FIG. 1, the top ring 1 is capable of holding a substrate such as the semiconductor wafer WH on the bottom face thereof. The top ring head 110 is configured to turning about the top ring head shaft 117, and the turning of the top ring head 110 causes the top ring 1 holding the semiconductor wafer WH on the bottom face to move from a semiconductor wafer WH receiving position to above the polishing table 100. Thereafter, the top ring 1 is lowered to press the semiconductor wafer WH against the surface (polishing surface) 101a of the polishing pad 101. At this time, the top ring 1 and the polishing table 100 are each made to rotate, and the polishing liquid is supplied onto the polishing pad 101 from the polishing liquid supply nozzle 102 provided above the polishing table 100. In this way, the surface of the semiconductor wafer WH is polished by causing the semiconductor wafer WH to slide against the surface 101a of the polishing pad 101.

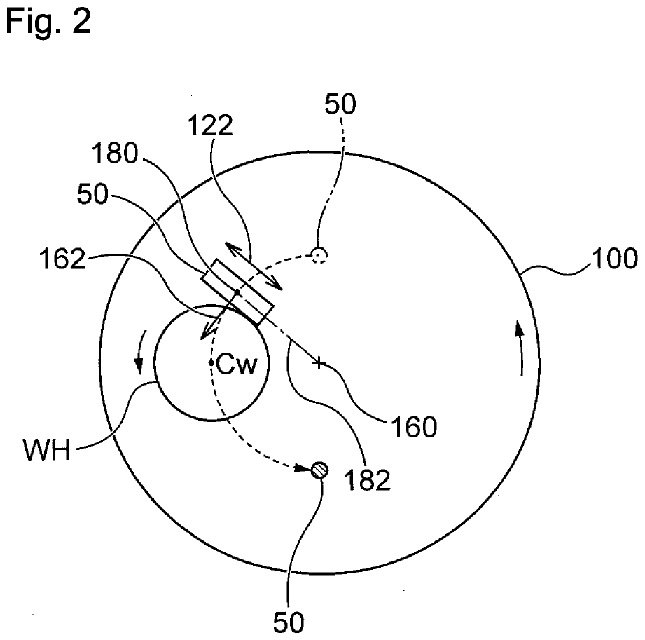

FIG. 2 is a plan view illustrating the relationship among the polishing table 100, the eddy current sensor 50, and the semiconductor wafer WH. As illustrated in FIG. 2, the eddy current sensor 50 is installed at a position that passes through a center Cw of the semiconductor wafer WH being polished that is held by the top ring 1. The polishing table 100 rotates about a rotation center 160. For example, the eddy current sensor 50 is capable of detecting a metal film (conductive film) such as a Cu layer of the semiconductor wafer WH continuously on a passage trajectory (scan line) while passing under the semiconductor wafer WH.

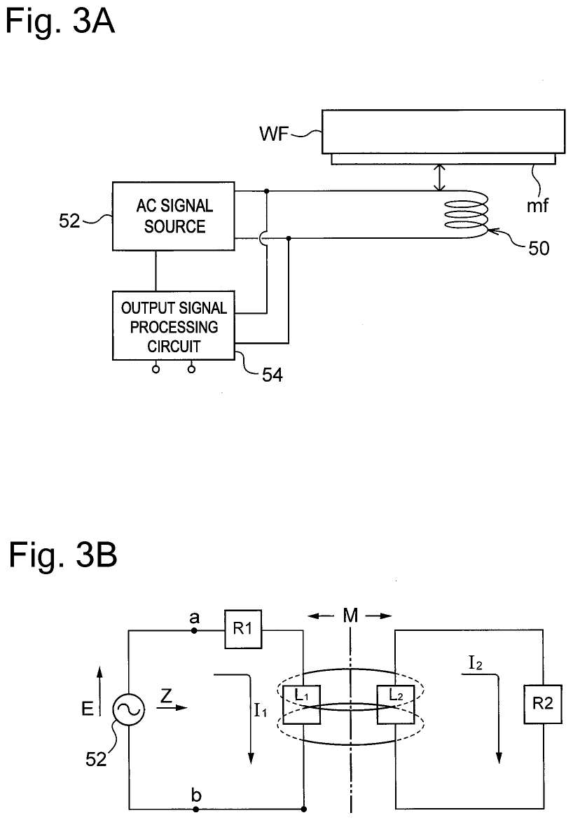

Next, the eddy current sensor 50 provided in the polishing apparatus according to the present invention will be described in further detail using the attached drawings. FIGS. 3A and 3B are diagrams illustrating a configuration of the eddy current sensor 50, in which FIG. 3A is a block diagram illustrating the configuration of the eddy current sensor 50 and FIG. 3B is an equivalent circuit diagram of the eddy current sensor 50.

As illustrated in FIG. 3A, the eddy current sensor 50 is disposed near a metal film (or conductive film) mf to be detected, and an alternating-current (AC) signal source 52 is connected to a coil of the eddy current sensor 50. Here, the metal film (or conductive film) mf to be detected is a thin film of a material such as Cu, Al, Au, or W formed on the semiconductor wafer WH, for example. The eddy current sensor 50 is disposed near the metal film (or conductive film) to be detected at a distance of approximately 1.0 mm to 4.0 mm for example.

Types of eddy current sensors include a frequency type that generates an eddy current in the metal film (or conductive film) mf to cause a change in the oscillating frequency and detects the metal film (or conductive film) from the frequency change, and an impedance type that generates an eddy current in the metal film (or conductive film) to cause a change in the impedance and detects the metal film (or conductive film) from the impedance change. In other words, with the frequency type, changing the eddy current I₂ causes the impedance Z to change in the equivalent circuit illustrated in FIG. 3B, and if the oscillating frequency of the signal source (a variable frequency oscillator) 52 changes, the change in the oscillating frequency can be detected by a detector circuit 54, and a change in the metal film (or conductive film) can be detected. With the impedance type, changing the eddy current I₂ causes the impedance Z to change in the equivalent circuit illustrated in FIG. 3B, and if the impedance Z as seen from the signal source (a fixed frequency oscillator) 52 changes, the change in the impedance Z can be detected by the detector circuit 54, and a change in the metal film (or conductive film) can be detected.

In an eddy current sensor of the impedance type, signal outputs X and Y, the phase, and the combined impedance Z are extracted as described later. From the frequency F or the impedances X, Y, and the like, measurement information about the metal film (or conductive film) of Cu, Al, Au, or W is obtained. As illustrated in FIG. 1, the eddy current sensor 50 can be built into the polishing table 100 at a position near the surface and positioned to face the semiconductor wafer to be polished through the polishing pad, such that changes in the metal film (or conductive film) can be detected from an eddy current flowing through the metal film (or conductive film) on the semiconductor wafer.

For the frequency of the eddy current sensor, a single radio wave, a mixed radio wave, AM-modulated radio waves. FM-modulated radio waves, the sweep output from a function generator, or a plurality of oscillating frequency sources can be used, and it is preferable to select an oscillating frequency and a modulation method with good sensitivity to match the type of metal film.

Hereinafter, an eddy current sensor of the impedance type will be described specifically. The AC signal source 52 is an oscillator of a fixed frequency approximately from 2 MHz to 30 MHz, for which a quartz oscillator is used for example. Additionally, a current I₁ flows through the eddy current sensor 50 due to an AC voltage supplied by the AC signal source 52. By causing a current to flow through the eddy current sensor 50 positioned near the metal film (or conductive film) mf, the flux links with the metal film (or conductive film) mf to form a mutual inductance M between the two, and an eddy current I₂ flows through the metal film (or conductive film) mf. Here, R1 is the equivalent resistance on the primary side that includes the eddy current sensor, and L₁ is the self-inductance on the primary side that similarly includes the eddy current sensor. On the metal film (or conductive film) mf side, R2 is the equivalent resistance corresponding to eddy current loss, and L₂ is the self-inductance thereof. The impedance Z seen on the eddy current sensor side from terminals a and b of the AC signal source 52 changes depending on the magnitude of the eddy current loss formed in the metal film (or conductive film) mf.

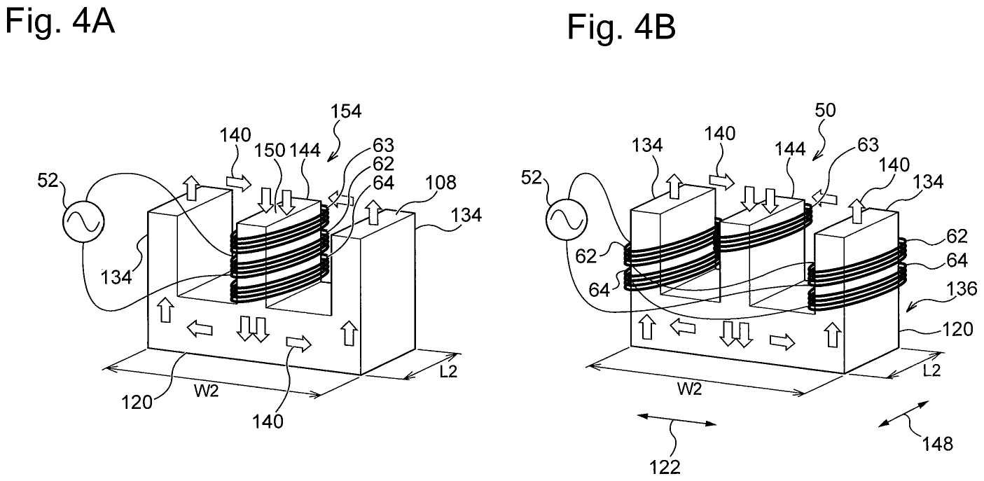

FIGS. 4A and 4B are diagrams illustrating a comparison of an eddy current sensor 154 according to the related art and the eddy current sensor 50 according to the present embodiment. FIG. 4A is a schematic diagram illustrating a configuration of the eddy current sensor 154 according to the related art, and FIG. 4B is a schematic diagram illustrating the configuration of the eddy current sensor 50 according to the present embodiment. The eddy current sensor 50 for detecting an eddy current which can be generated in a conductor includes a magnetic core 136 having a base 120, a central wall 144 provided on the base 120 in the center of the base 120 in a first direction 122, and two end walls 134 provided on the base 120 at opposite ends (either end portion) of the base 120 in the first direction 122. The two end walls 134 face each other. The core 136 is an “E” core.

The eddy current sensor 50 includes two exciting coils 62, disposed on the end walls 134, that can generate an eddy current in a conductor, a detecting coil 63, disposed on the central wall 144, that detects the eddy current, and a dummy coil 64, disposed on the end walls 134, that extracts the eddy current. The dummy coil 64 can be disposed on either the central wall 144 or the end walls 134. In the eddy current sensor 154 according to the related art illustrated in FIG. 4A, the exciting coil 62 is disposed on the central wall 144.

The thick arrows 140 illustrated in FIGS. 4A and 4B indicate the flux generated by the exciting coils 62. Inside the core 136, the flux indicated by the arrows 140 flows from the central wall 144 toward the end walls 134 through the base 120, or from the end walls 134 toward the central wall 144 through the base 120. Outside the core 136, the flux indicated by the arrows 140 flows from the end walls 134 toward the central wall 144 through space, or from the central wall 144 toward the end walls 134 through space.

FIGS. 4A and 4B illustrate the same state of the arrows 140, that is, the state of flux, between the eddy current sensor 154 according to the related art and the eddy current sensor 50 according to the present embodiment. However, this is a simplified illustration of the state of flux. The detailed state of the flux generated by the exciting coils 62 is different between the eddy current sensor 50 and the eddy current sensor 154, as described later.

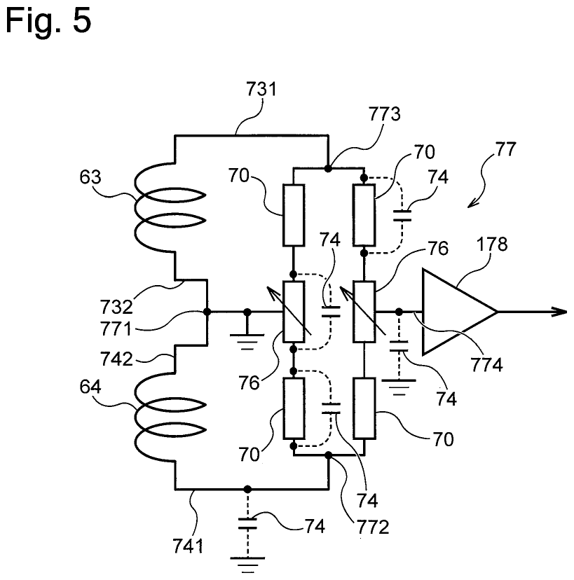

At this point, problems in the bridge circuit of the related art will be described with reference to FIG. 5. FIG. 5 is a schematic diagram of an example of the bridge circuit. In this example, a resistance bridge circuit 77 is used. As illustrated in FIG. 5, the detecting coil 63 and the dummy coil 64 are connected in reverse phase with each other. The detecting coil 63 and the dummy coil 64 form a reverse-phase series circuit, both ends of which are connected to a resistance bridge circuit 77 including a variable resistance 76.

Specifically, a signal line 731 of the detecting coil 63 is connected to a terminal 773 of the resistance bridge circuit 77, and a signal line 732 of the detecting coil 63 is connected to a terminal 771 of the resistance bridge circuit 77. A signal line 741 of the dummy coil 64 is connected to a terminal 772 of the resistance bridge circuit 77, and a signal line 742 of the dummy coil 64 is connected to the terminal 771 of the resistance bridge circuit 77. The terminal 771 is grounded. A terminal 774 of the resistance bridge circuit 77 is the sensor output. The sensor output is sent to the detector circuit 54 after being amplified by an amplifier 178. Note that a resistance 70 is a fixed resistance.

The resistance value of the variable resistance 76 is adjusted such that the output voltage of the series circuit containing the detecting coil 63 and the dummy coil 64 is zero when a metal film (or conductive film) is not present, or in other words, such that the signals from the detecting coil 63 and the dummy coil 64 are signals of equal amplitude in antiphase. However, with the detection method using the resistance bridge circuit 77 according to the related art, the resistance values of the resistances 70 and 76 may change in response to changes in the ambient temperature due to the properties of the resistance bridge circuit 77. Moreover, the circuit is also susceptible to nearby changes such as the floating capacitance 74 of the resistances 70, 76, and the like, and there is a problem in that the zero-point adjustment may shift. Because the output of the resistance bridge circuit 77 is a weak signal, changes in the zero-point due to nearby changes are non-negligible.

To provide an eddy current sensor that is less susceptible to changes in the surrounding environment compared to the related art, the present embodiment provides the eddy current sensor 50 that does not require a bridge circuit. A bridge circuit is useful for detecting weak signals, and consequently not using a bridge circuit necessitates an increase in the strength of the eddy current that is the target of detection by the detecting coil 63. For this reason, in the present embodiment, the exciting coils 62 capable of generating an eddy current in a conductor is disposed on the end walls 134, as illustrated in FIG. 4B.

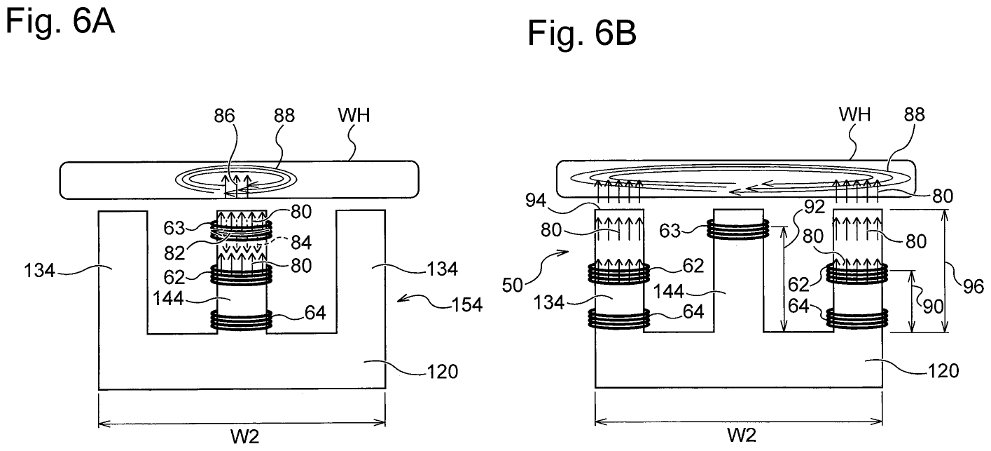

FIGS. 6A and 6B will be referenced to describe how disposing the exciting coils 62 on the end walls 134 increases the strength of the eddy current that is the target of detection by the detecting coil 63 and causes the detection signal from the detecting coil 63 to be larger. FIG. 6A is a diagram illustrating the flux of the eddy current sensor 154 according to the related art, and FIG. 6B is a diagram illustrating the flux of the eddy current sensor 50 according to the embodiment of the present invention.

As illustrated in FIG. 6A, the exciting coil 62 of the related art is disposed together with the detecting coil 63 on the central wall 144. In this case, the flux penetrating the wafer WH treated as the object to be polished decreases. In other words, if flux 80 is generated by the exciting coil 62, the flux 80 enters the wafer WH and also penetrates into the detecting coil 63. Consequently, the flux inside the detecting coil 63 changes, a counter electromotive force 82 is produced in the detecting coil 63 so as to cancel out the flux 80 generated by the exciting coil 62, and the detecting coil 63 generates flux 84 in the opposite direction.

As a result of the generation of the flux 84 in the opposite direction, the flux 86 penetrating the wafer WH is reduced. The reduction of the flux 86 penetrating the wafer WH leads to a reduced eddy current 88 in the wafer WH. Because the eddy current 88 is reduced, the flux generated inside the detecting coil 63 by the eddy current 88 is reduced. The detecting coil 63 detects and outputs this flux as a signal related to the film thickness, and therefore the output signal 731 of the eddy current sensor 154 (see FIG. 5) is weakened.

On the other hand, in the present embodiment, the exciting coils 62 is disposed on the end walls 134 as illustrated in FIG. 6B, and therefore less of the flux 80 generated by the exciting coils 62 penetrates into the detecting coil 63 compared to the related art. The reason why less of the flux 80 penetrates into the detecting coil 63 compared to the related art will be described later. Consequently, the flux 84 in the opposite direction generated by the detecting coil 63 is reduced compared to the related art. Because there is less flux 84 in the opposite direction working to cancel out the flux 80, the eddy current 88 in the wafer WH is increased compared to the related art. Because the eddy current 88 is increased compared to the related art, the output signal 731 from the eddy current sensor 50 is strengthened.

The reason why less of the flux 80 generated by the exciting coils 62 penetrates into the detecting coil 63 compared to the related art is as follows. Whether or not less of the flux 80 generated by the exciting coils 62 on the end walls 134 penetrates into the detecting coil 63 on the central wall 144 depends on the size of the end walls 134, that is, the cross-sectional area of the end walls 134. As the cross-sectional area of the end walls 134 (cores) decreases, the flux leaking outside the end walls 134 (cores) increases, and less of the flux 80 flows from the end walls 134 through the base 120 to the detecting coil 63 on the central wall 144.

The present embodiment focuses on the property by which the flux leaking outside the end walls 134 increases as the cross-sectional area of the end walls 134 decreases. In the present embodiment, this property is used to reduce the flux in the opposite direction generated by the detecting coil 63 on the central wall 144 by disposing the exciting coils 62 on the end walls 134. If the exciting coil 62 is disposed on the central wall 144 like the related art, the detecting coil 63 is adjacent to the exciting coil 62, and consequently decreasing the cross-sectional area of the central wall 144 has little effect on reducing the flux 80 penetrating the detecting coil 63.

In the present embodiment, because the exciting coils are disposed on the end walls 134 distanced from the central wall 144, when the cross-sectional area of the magnetic end walls 134 is small, less of the flux 80 passes through the magnetic end walls 134 and the central wall 144 to reach the detecting coil 63. As a result, the flux 84 in the opposite direction generated by the detecting coil 63 can be reduced reliably.

Note that as illustrated in FIGS. 4A and 4B, the exciting coils 62 is connected to the AC signal source 52. The exciting coils 62 creates the flux 80 when supplied with an AC voltage from the AC signal source 52, and the flux 80 creates an eddy current in the metal film (or conductive film) mf on the semiconductor wafer WH disposed near the eddy current sensor 50. The detecting coil 63 detects the flux generated by the eddy current 88 created in the metal film. The dummy coil 64 is disposed on the opposite side away from the wafer WH with the exciting coils 62 in between.

Note that because the resistance bridge circuit 77 is not used in the present embodiment, a dummy coil does not have to be provided for the resistance bridge circuit 77. The reason for using the dummy coil 64 in the present embodiment will be described later. The dummy coil 64 disposed near the exciting coils 62 generates a reverse magnetic field from the exciting coils 62, similarly to the detecting coil 63. In consideration of this point, it is preferable not to install the dummy coil 64, or to reduce the reverse magnetic field that is generated. For example, the reverse magnetic field generated by the dummy coil 64 can be reduced by decreasing the number of coil windings in the dummy coil 64.

Note that although the resistance bridge circuit 77 is not used in the present embodiment, the resistance bridge circuit 77 may be used. For example, if the eddy current sensor according to the present embodiment is used in combination with a bridge circuit such as the resistance bridge circuit 77 for use cases where there is little temperature change, it is possible to obtain the two merits of (1) the ability to extract a weaker signal by using the bridge circuit, and (2) a large sensor output. Note that the exciting coils 62 and the dummy coil 64 may be disposed at the same positions on the end walls 134.

In FIGS. 4A and 4B, a width W2 of the base 120 in the first direction 122 is equal to or greater than a length L2 of the base 120 in a second direction 148 substantially orthogonal to the first direction. In other words, the first direction 122 is the longitudinal direction of the base 120 in the present embodiment. However, the width W2 of the base 120 in the first direction 122 may be shorter than the length L2 of the base 120 in the second direction 148.

The end walls 134 and the central wall 144 have a rectangular shape in a plan view, but are not limited to a rectangular shape, and may also have a square, elliptical, polygonal, or circular shape or the like. Likewise, the base 120 has a rectangular shape in a plan view, but is not limited to a rectangular shape, and may also have a square, elliptical, polygonal, or circular shape or the like. The core 136 is magnetic. The core 136 is an “E” core having the central wall 144 provided on the base 120 in the center of the base 120 in the first direction 122.

In FIG. 6B, a distance 90 on the end walls 134 from the center of the exciting coils 62 to the base 120 in the second direction 148 is shorter than a distance 92 on the central wall 144 from the center of the detecting coil 63 to the base 120 in the second direction 148. The reason why the distance 90 is shorter than the distance 92 is to keep the exciting coils 62 away from the detecting coil 63. If the exciting coils 62 is disposed close the detecting coil 63, such as at the end 94 of the end walls 134 for example, the exciting coils 62 and the detecting coil 63 will be close to each other. In this case, the flux 80 generated by the exciting coils 62 will flow directly to the detecting coil 63 through the space (rather than through the end walls 134, the base 120, and the central wall 144). If the flux 80 flows directly to the detecting coil 63, a reverse magnetic field will be generated similarly to the mechanism described above and obstruct the detection of the flux from the eddy current 88 by the detecting coil 63, and the output from the detecting coil 63 will be weakened.

The exciting coils 62 is preferably close to the wafer WH, and therefore the exciting coils 62 is preferably disposed at the tip of the end walls 134. On the other hand, it is preferable to separate the exciting coils 62 from the detecting coil 63 as described above. For this reason, it is preferable to lower the exciting coils 62 from the tip of the end walls 134. For example, the distance 90 on the end walls 134 from the exciting coils 62 to the base 120 is preferably no more than half a distance 96 on the end walls 134 from the end 94 of the end walls 134 facing the conductor (wafer WH) to the base 120.

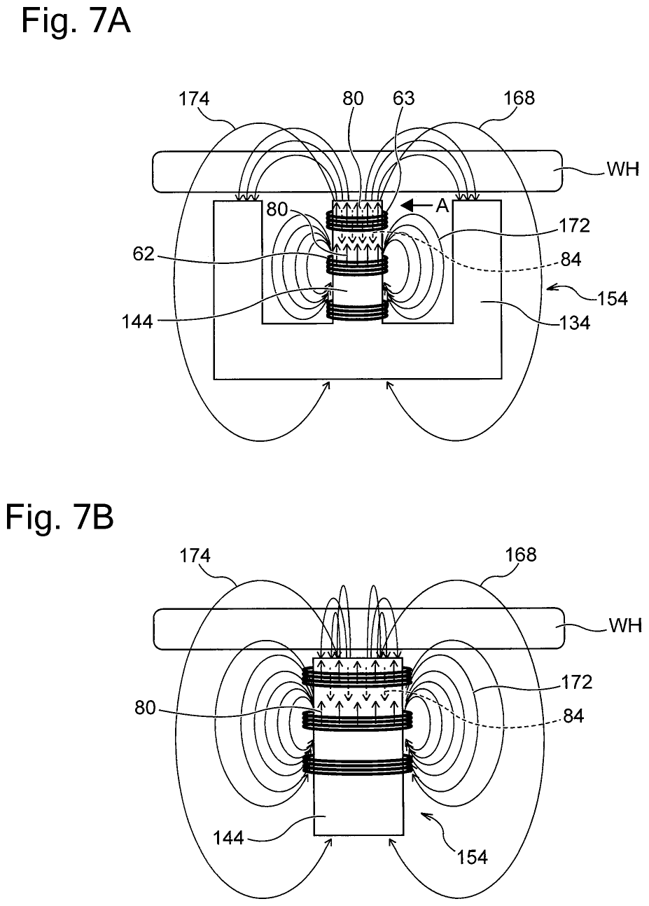

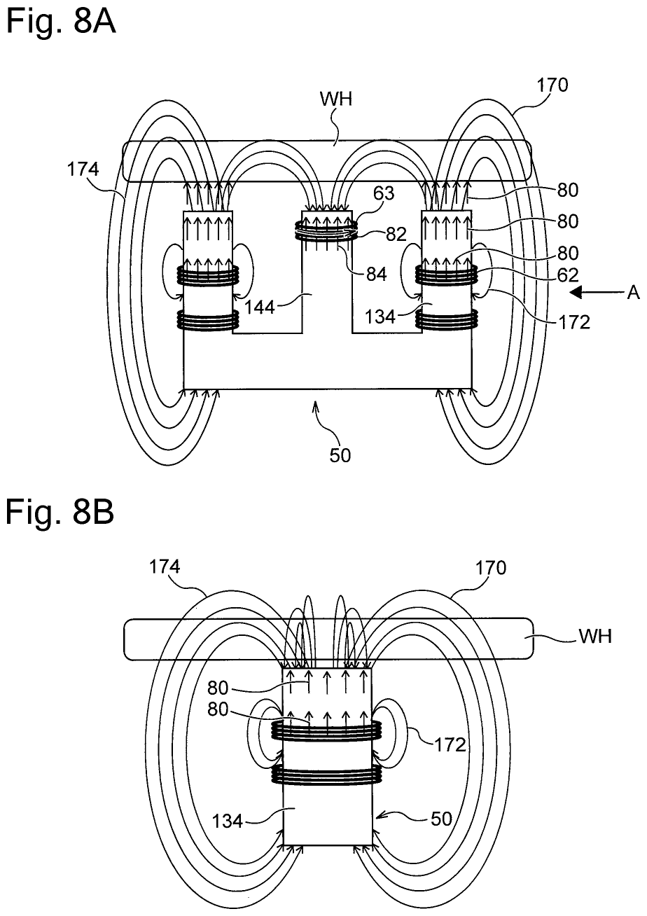

The reason why the eddy current 88 illustrated in FIGS. 6A and 6B is generated will be described further with reference to FIGS. 7A and 7B and FIGS. 8A and 8B. FIGS. 7A and 7B are diagrams illustrating flux 168 generated by the eddy current sensor 154 according to the technology of the related art. FIGS. 8A and 8B are diagrams illustrating flux 170 generated by the eddy current sensor 50 according to the present embodiment. FIG. 7A is a front view of the eddy current sensor 154, similar to FIG. 6A. FIG. 7B is a side view of the eddy current sensor 154 as seen from the direction A in FIG. 7A. FIG. 8B is a front view of the eddy current sensor 50, similar to FIG. 6B, and FIG. 8B is a side view of the eddy current sensor 50 as seen from the direction A in FIG. 8A.

In FIGS. 7A and 7B, the flux 168 generated by the eddy current sensor 154 includes flux 174 that penetrates the wafer WH and flux 172 that does not penetrate the wafer WH. The flux of the exciting coil 62 is reduced by the flux 84 in the opposite direction generated in the detecting coil 63, thereby decreasing the flux 174 that penetrates the wafer WH and increasing the flux 172 that does not penetrate the wafer WH (does not reach the wafer WH). In other words, the eddy current 88 on the wafer WH is small.

In FIGS. 8A and 8B, the flux 170 generated by the eddy current sensor 50 likewise includes the flux 174 that penetrates the wafer WH and the flux 172 that does not penetrate the wafer WH. The flux 174 that penetrates the wafer WH generated by the exciting coils 62 penetrates the wafer WH without passing through the central wall 144 and being influenced by the flux of the detecting coil 63. Because the detecting coil 63 is positioned away from the exciting coils 62, the influence of the flux 84 generated by the detecting coil 63 is small, and there is more of the flux 174 that penetrates the wafer WH. In both the eddy current sensor 154 according to the related art and the eddy current sensor 50 according to the present embodiment, the reduction in the flux passing through the detecting coil 63 under the influence of the reverse magnetic field of the detecting coil 63 is the same, but the amount of the flux 174 that penetrates the wafer WH is different between the eddy current sensor 154 and the eddy current sensor 50.

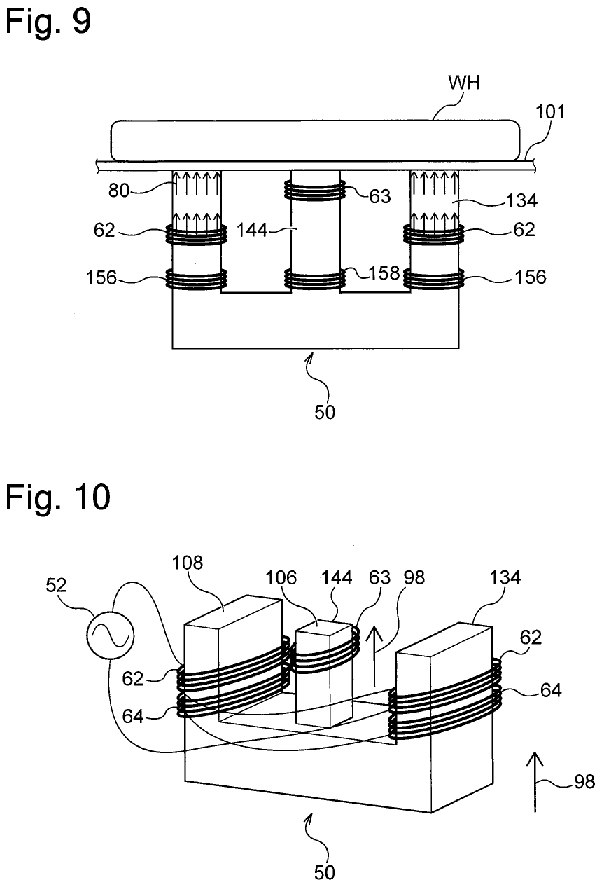

Next, the function of the dummy coil 64 in the present embodiment will be described with reference to FIG. 9. FIG. 9 is a schematic diagram for explaining the function of the dummy coil 64. The dummy coil 64 has a function (1) of stabilizing the flux by correcting variations in the flux generated by the exciting coils 62, and a function (2) of detecting changes in the influence of the eddy current 88 on the dummy coil 64 due to the distance from the wafer WH to the dummy coil 64. Note that the above two functions can be achieved in the case where the dummy coil 64 is provided on the end walls 134 (the dummy coil 64 in this case is designated by the dummy coil 156) and also in the case where the dummy coil 64 is provided on the central wall 144 (the dummy coil 64 in this case is designated by the dummy coil 158).

The function (1) of stabilizing the flux will be described. The dummy coil 64 is disposed on the portion of the end walls 134 or the central wall 144 that is close to the base 120, or in other words, at the base of the end walls 134 or the central wall 144. For this reason, the dummy coil 64 is distanced from the wafer WH, and signal (dummy signal) output by the dummy coil 64 is only weakly influenced by the eddy current 88 on the wafer WH. Accordingly, the dummy coil 64 is mainly influenced by the flux 80 generated by the exciting coils 62. Consequently, the dummy coil 64 can be used to monitor variations in the flux 80 generated by the exciting coils 62 and control the output of the AC signal source 52. For example, the output of the exciting coils 62 can be corrected by a feedback control.

Next, the function (2) of detecting changes in the influence of the eddy current 88 on the dummy coil 64 due to the distance from the wafer WH to the dummy coil 64 will be described. When the film thickness is the same, changes in the difference between the detection signal output by the detecting coil 63 and the output signal of the dummy coil 64 can be monitored to extract changes in the detection signal of the detecting coil 63 due to changes in the distance from the wafer WH. The extracted signal can be converted into the distance from the wafer WH to the detecting coil 63 (that is, the thickness of the pad 101) and used to monitor the decrease in the thickness of the pad 101 or the like.

The reason for being able to monitor changes in the distance from the wafer WH is as follows. When the film thickness is the same, changes in the output from the detecting coil 63 and the output from the dummy coil 64 may be induced by variations in the excitation signal in addition to the variations in the thickness of the pad 101 described above. The variations in the excitation signal are thought to be influenced equally by the output from the detecting coil 63 and the output from the dummy coil 64. For this reason, by taking the difference between the output from the detecting coil 63 and the output from the dummy coil 64, the influence of the variations in the excitation signal can be canceled out. With regard to the influence of variations in thickness, the dummy coil 64 is distant from the wafer WH, and therefore the signal output by the dummy coil 64 is only weakly influenced by the eddy current 88 on the wafer WH (variations in thickness). Consequently, it is possible to detect only the variations in the thickness of the pad 101 described above.

Next, the shapes of the walls will be described with reference to FIG. 10. FIG. 10 is a schematic diagram illustrating a configuration of an eddy current sensor according to another embodiment of the present invention. The cross-sectional area 106 of the central wall 144 perpendicular to a third direction 98 proceeding from the base 120 toward the wafer WH is smaller than the cross-sectional area 108 of the end walls 134 perpendicular to the third direction 98. On the other hand, in the eddy current sensor of the related art illustrated in FIG. 4A, the cross-sectional area 150 of the central wall 144 perpendicular to the third direction 98 is the same as the cross-sectional area 108 of the end walls 134 perpendicular to the third direction 98.

The effects of the eddy current sensor illustrated in FIG. 10 will be described. To improve the resolving power of the eddy current sensor, it is necessary to decrease the detection spot diameter of the eddy current sensor. The detection spot diameter is the size of the region on the wafer WH that is detectable by the detecting coil 63. The detection spot diameter is influenced by the size of the cross-sectional area of the central wall 144 around which the detecting coil 63 is wound. If the size of the cross-sectional area of the central wall 144 is reduced to decrease the detection spot diameter when the exciting coil 62 is disposed on the central wall 144 like in the related art, the following problem occurs.

If the size of the cross-sectional area of the central wall 144 is reduced, the magnitude of the flux generated by the exciting coil 62 is also reduced. The reason why the magnitude of the flux is reduced is that the reduction in the cross-sectional area of the central wall 144 causes the flux 80 generated by the exciting coil 62 to leak out from the central wall 144 as described above. If the cross-sectional area is small, exciting flux leaks out near the exciting coil 62. In other words, when the exciting coil 62 is positioned in the middle of the central wall 144 like in the related art, the flux 80 leaks out along the way from the exciting coil 62 to the wafer WH. Because a large quantity of the exciting flux 80 leaks out, the eddy current 88 generated by the flux 80 is decreased.

In the embodiment illustrated in FIG. 10, the exciting coils 62 is wound around the thick end walls 134 rather than the thin central wall 144, and therefore the flux 80 reaches the wafer with less leakage. In the eddy current sensor 50 according to the present embodiment, by changing the sizes of the central wall 144 and the end walls 134, the detection spot diameter can be decreased without reducing the magnitude of the eddy current generated in the wafer WH. Namely, a large eddy current can be generated because the end walls 134 are thick, and additionally, the detection spot diameter is small because the central wall 144 is thin (that is, the detecting coil is small). The end walls 134 and the central wall 144 may have cylindrical or cuboid shapes and still have the same functions.

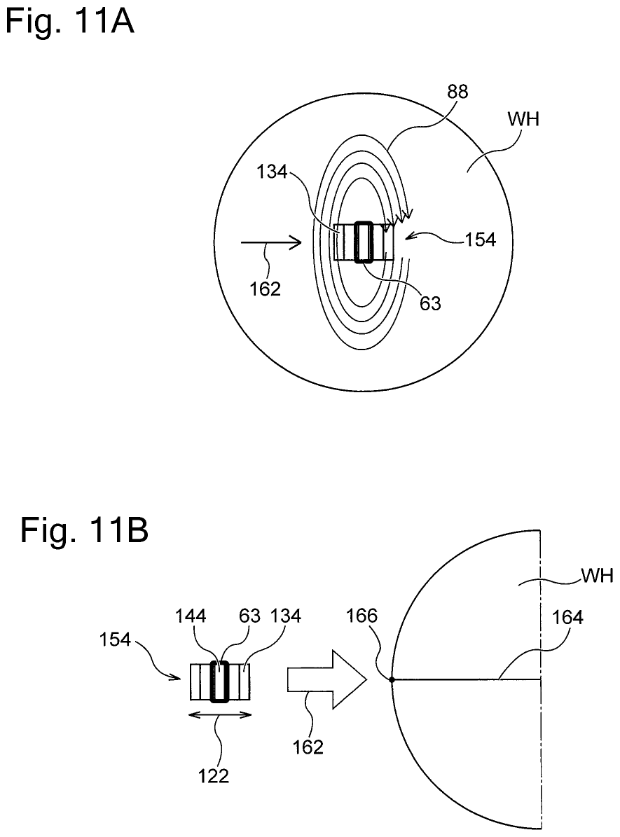

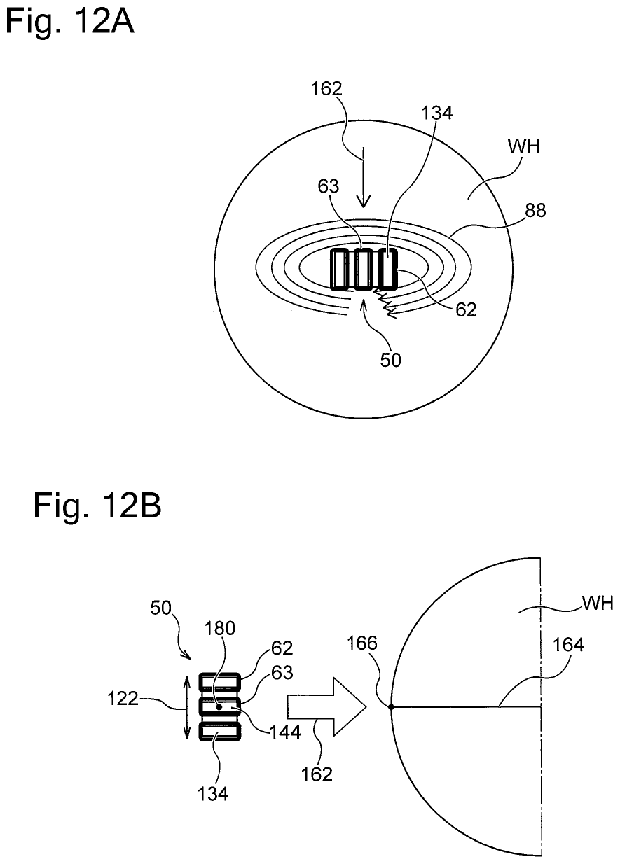

Next, a movement direction 162 in which the eddy current sensor 50 moves from the outside of the wafer WH toward the inside of the wafer WH in accordance with the rotation of the polishing table 100 will be described with reference to FIGS. 11A and 11B and FIGS. 12A and 12B. FIGS. 11A and 11B are diagrams illustrating relationship between the movement direction 162 of the eddy current sensor 154 according to a Comparative Example and the first direction 122. FIGS. 12A and 12B are diagrams illustrating relationship between the movement direction 162 of the eddy current sensor 50 according to the present embodiment and the first direction 122. FIGS. 11A and 12A are plan views illustrating the state when the eddy current sensors 154 and 50 are directly underneath the center of the wafer WH. FIGS. 11B and 12B are plan views illustrating the state immediately before the eddy current sensors 154 and 50 move from outside the wafer WH to inside the wafer WH (the state near the edge of the wafer WH).

In FIG. 11B, the movement direction 162 is substantially parallel to the first direction 122. In FIG. 12B, the movement direction 162 is substantially orthogonal to the first direction 122.

The arrangement illustrated in FIG. 12B is more preferable than the arrangement illustrated in FIG. 11B. The reason why the arrangement illustrated in FIG. 12B is preferable will be described with reference to FIGS. 11A and 12A. A comparison of FIGS. 11A and 12A shows that the difference in the arrangement of the exciting coils 62 creates a difference in the elliptical shape of the strength distribution of the eddy current 88 generated inside the wafer WH by the excitation signal. In FIG. 11A, the eddy current 88 has a narrow spread and the gradient of the eddy current strength distribution is steep in the first direction 122. The spread of the eddy current 88 is wider in the direction orthogonal to the first direction 122 than the first direction 122.

On the other hand, in FIG. 12A, the eddy current 88 has a narrow spread and the gradient of the eddy current strength distribution is steep in the direction orthogonal to the first direction 122. The spread of the eddy current 88 is wider in the first direction 122 than the direction orthogonal to the first direction 122. By causing the angle of entrance by the eddy current sensors 154 and 50 with respect to the wafer WH to be an angle at which the gradient of the eddy current strength distribution is steep, the spot diameter of the eddy current sensors 154 and 50 can be decreased, and the resolving power in the temporal direction (spatial direction) is improved. Consequently, in the Comparative Example, it is preferable to enter the wafer WH in the first direction 122, whereas in the present embodiment, it is preferable to enter the wafer WH in the direction orthogonal to the first direction 122.

Note that in the case where the eddy current sensors 154 and 50 are installed inside the polishing table 100 and rotate together with the polishing table 100 as illustrated in FIG. 2, the first direction 122 is preferably the same as the direction 182 joining the center 180 of the core 136 to the rotation center 160 of the polishing table 100 (this is the radial direction of the polishing table 100 at the center 180). In this case, the direction in which the eddy current sensor 50 rotates in accordance with the rotation of the polishing table 100 (the movement direction 162 of the eddy current sensor 50 at the center 180) is orthogonal to the direction 182 joining the center 180 of the core 136 to the rotation center 160 of the polishing table 100. If the first direction 122 is aligned with the radial direction of the polishing table 100 at the center 180 of the core 136 in this way, the angle of entrance and the angle of exit by the eddy current sensors 154 and 50 (core 136) with respect to the wafer WH are equal. Having equal angles of entrance and exit is preferable from the standpoint of the simplicity of data processing (that is, the simplicity of controlling the film thickness).

Note that the core 136 may be provided with a ferrite material such as MnZn ferrite. NiZn ferrite, or another type of ferrite. The conducting wire used in the detecting coil 63, the exciting coils 62, and the dummy coil 64 is copper. Manganin wire, nichrome wire, or the like. The use of Manganin wire or nichrome wire results in fewer temperature changes due to electrical resistance and the like, and the temperature properties are improved. The eddy current sensor 50 may be entirely covered by a material such as resin.

A method of controlling each unit of the polishing apparatus on the basis of the film thickness obtained by the sensor 50 will be described hereinafter. As illustrated in FIG. 1, the eddy current sensor 50 is connected to an endpoint detection controller 246, and the endpoint detection controller 246 is connected to an equipment controller 248. The output signal from the eddy current sensor 50 is sent to the endpoint detection controller 246. The endpoint detection controller 246 performs necessary processing (arithmetic processing and correction) on the output signal from the eddy current sensor 50 to generate a monitoring signal (film thickness data corrected by the endpoint detection controller 246). The equipment controller 248 controls components such as the top ring motor 114 and a motor for the polishing table 100 (not illustrated) on the basis of the corrected film thickness data.

The equipment controller 248 which is a main controller includes a CPU, a memory, a recording medium and software recorded in the recording medium or the like. The equipment controller 248 performs monitoring or control of the entire polishing apparatus, exchanges signals therefor, records information or carries out calculations. The equipment controller 248 exchanges signals mainly with an endpoint detection controller 246. The endpoint detection controller 246 also includes a CPU, a memory, a recording medium and software recorded in the recording medium or the like.

The foregoing describes exemplary embodiments of the present invention, but the embodiments described above are for facilitating the understanding of the present invention, and do not limit the present invention. The present invention may be modified and improved without departing from the gist of the invention, and any equivalents obtained through such modification and improvement obviously are included in the present invention. Furthermore, any combination or omission of the components described in the claims and the specification is possible insofar as at least one or some of the issues described above can be addressed, or insofar as at least one or some of the effects are exhibited.

This application claims priority under the Paris Convention to Japanese Patent Application No. 2020-195199 filed on Nov. 25, 2020. The entire disclosure of Japanese Patent Laid-Open No. 2011-23579 including specification, claims, drawings and summary is incorporated herein by reference in its entirety.

### REFERENCE SIGNS LIST

WH wafer
50 eddy current sensor
62 exciting coil
63 detecting coil
64 dummy coil
77 resistance bridge circuit
80, 84, 86 flux
88 eddy current
90, 92, 96 distance
94 end
98 third direction
100 polishing table
101 polishing pad
106, 108, 150 cross-sectional area
110 top ring head
120 base
122 first direction
134 end wall
144 central wall
148 second direction
154 eddy current sensor
156 dummy coil
158 dummy coil
160 rotation center
162 movement direction
164 radial direction
166 point
168, 170, 172, 174 flux

What is claimed is:

1. An eddy current sensor for detecting an eddy current that can be generated in a conductor, the eddy current sensor comprising:
a magnetic core having a base, a central wall provided on the base in a center of the base in a first direction, and end walls provided on the base at either end portion of the base in the first direction;
exciting coils, disposed on the end walls, that are configured to generate an eddy current in the conductor; and
a detecting coil, disposed on the central wall, that is configured to detect the eddy current.

2. The eddy current sensor according to claim 1, wherein a distance on the end walls from the exciting coils to the base is shorter than a distance on the central wall from the detecting coil to the base.

3. The eddy current sensor according to claim 1, wherein a distance on the end walls from the exciting coils to the base is no more than half a distance on the end walls from ends facing the conductor to the base.

4. The eddy current sensor according to claim 1, further comprising a dummy coil, disposed on either the central wall or the end walls, that is configured to detect the eddy current.

5. The eddy current sensor according to claim 1, wherein a cross-sectional area of the central wall perpendicular to a second direction proceeding from the base toward the conductor is smaller than a cross-sectional area of the end walls perpendicular to the second direction.

6. A polishing apparatus comprising:
a polishing table to which a polishing pad is attached for polishing a substrate containing the conductor;
a motor configured to rotationally drive the polishing table;
a top ring configured to hold the substrate and press the substrate against the polishing pad,
the eddy current sensor according to claim 1, disposed inside the polishing table and configured to detect the eddy current created in the conductor; and
an endpoint detection controller configured to calculate film thickness data about the conductor from the detected eddy current.

7. The polishing apparatus according to claim 6, wherein the first direction is substantially the same as a direction joining a center of the core to a rotation center of the polishing table.
